(19) United States
(12) Patent Application Publication
(10) Pub. No.: US 2008/0265239 A1
(43) Pub. Date: Oct. 30, 2008

(54) INTEGRATED CIRCUIT INCLUDING SPACER MATERIAL LAYER

(76) Inventors: Jan Boris Philipp, Peekskill, NY (US); Thomas Happ, Tarrytown, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/740,657

(22) Filed: Apr. 26, 2007

(51) Int. Cl. H01L 45/00

(52) U.S. Cl. 257/4; 438/102; 257/E45.003

(57) ABSTRACT

An integrated circuit includes a first electrode and a dielectric material layer contacting a first portion of the first electrode. The integrated circuit includes a spacer material layer contacting a sidewall portion of the dielectric material layer and a second portion of the first electrode. The second portion is within the first portion. The integrated circuit includes resistivity changing material contacting the spacer material layer and a third portion of the first electrode. The third portion is within the second portion. The integrated circuit includes a second electrode contacting the resistivity changing material.

### BACKGROUND

One type of memory is resistive memory. Resistive memory utilizes the resistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory. Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store bits of data. In the following description, the amorphous state generally refers to the state having the higher resistivity and the crystalline state generally refers to the state having the lower resistivity.

Phase changes in the phase change materials may be induced reversibly. In this way, the memory may change from the amorphous state to the crystalline state and from the crystalline state to the amorphous state in response to temperature changes. The temperature changes to the phase change material may be achieved by driving current through the phase change material itself or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The level of current and/or voltage generally corresponds to the temperature induced within the phase change material in each memory cell. To minimize the amount of power that is used to program each memory cell, the interface area between the phase change material and at least one electrode of the memory cell should be minimized.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. To program a phase change memory cell to an intermediate resistance value, the amount of crystalline material coexisting with amorphous material and hence the cell resistance is controlled via a suitable write strategy.

For these and other reasons, there is a need for the present invention.

### SUMMARY

One embodiment provides an integrated circuit. The integrated circuit includes a first electrode and a dielectric material layer contacting a first portion of the first electrode. The integrated circuit includes a spacer material layer contacting a top portion and a sidewall portion of the dielectric material layer and a second portion of the first electrode. The second portion is within the first portion. The integrated circuit includes resistivity changing material contacting the spacer material layer and a third portion of the first electrode. The third portion is within the second portion. The integrated circuit includes a second electrode contacting the resistivity changing material.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a system.

FIG. 2 is a block diagram illustrating one embodiment of a memory device.

FIG. 3A illustrates a cross-sectional view of one embodiment of a phase change memory cell.

FIG. 3B illustrates a cross-sectional view of another embodiment of a phase change memory cell

FIG. 4 illustrates a cross-sectional view of one embodiment of a preprocessed wafer.

FIG. 5 illustrates a cross-sectional view of one embodiment of the preprocessed wafer, a first dielectric material layer, a second dielectric material layer, and a third dielectric material layer.

FIG. 6 illustrates a cross-sectional view of one embodiment of the preprocessed wafer, the first dielectric material layer, the second dielectric material layer, and the third dielectric material layer after etching the third dielectric material layer and the second dielectric material layer.

FIG. 7 illustrates a cross-sectional view of one embodiment of the preprocessed wafer, the first dielectric material layer, the second dielectric material layer, and the third dielectric material layer after etching the second dielectric material layer.

FIG. 8 illustrates a cross-sectional view of one embodiment of the preprocessed wafer, the first dielectric material layer, the second dielectric material layer, the third dielectric material layer, and a keyhole formed in a poly-Si layer.

FIG. 9 illustrates a cross-sectional view of one embodiment of the preprocessed wafer, the first dielectric material layer, the second dielectric material layer, and the poly-Si layer after etching the poly-Si layer and the first dielectric material layer.

FIG. 10 illustrates a cross-sectional view of one embodiment of the preprocessed wafer and the first dielectric material layer after removing the poly-Si layer and the second dielectric material layer.

FIG. 11 illustrates a cross-sectional view of one embodiment of the preprocessed wafer, the first dielectric material layer, and a spacer material layer.

FIG. 12 illustrates a cross-sectional view of one embodiment of the preprocessed wafer, the first dielectric material layer, and the spacer material layer after etching the spacer material layer.

FIG. 13 illustrates a cross-sectional view of one embodiment of the preprocessed wafer, the first dielectric material layer, the spacer material layer, and a phase change material layer.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

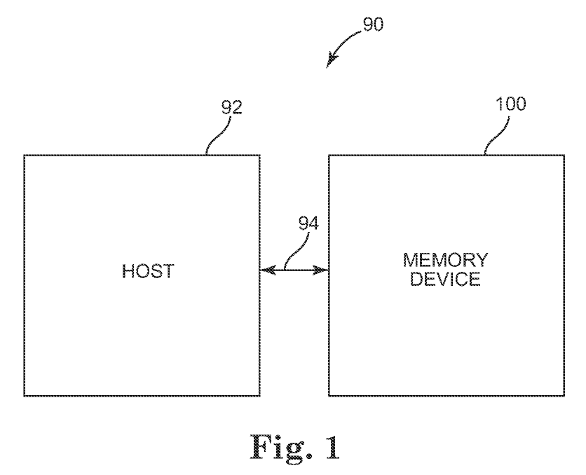

FIG. 1 is block diagram illustrating one embodiment of a system 90. System 90 includes a host 92 and a memory device 100. Host 92 is communicatively coupled to memory device 100 through communication link 94. Host 92 includes a computer (e.g., desktop, laptop, handheld), portable electronic device (e.g., cellular phone, personal digital assistant (PDA), MP3 player, video player), or any other suitable device that uses memory. Memory device 100 provides memory for host 92. In one embodiment, memory device 100 includes a phase change memory device.

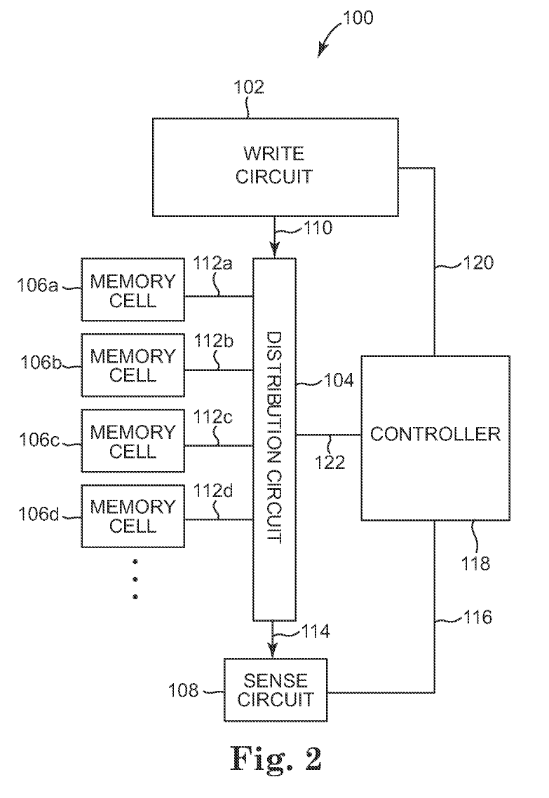

FIG. 2 is a block diagram illustrating one embodiment of memory device 100. Memory device 100 includes a write circuit 102, a distribution circuit 104, memory cells 106a, 106b, 106c, and 106d, a controller 118, and a sense circuit 108. Each of the memory cells 106a-106d is a phase change memory cell that stores data based on the amorphous and crystalline states of phase change material in the memory cell. Also, each of the memory cells 106a-106d can be programmed into one of two or more states by programming the phase change material to have intermediate resistance values. To program one of the memory cells 106a-106d to an intermediate resistance value, the amount of crystalline material coexisting with amorphous material and hence the cell resistance is controlled using a suitable write strategy.

Each of the memory cells 106a- 106b is a pore memory cell device. The pore is formed in dielectric material. The pore is filled with resistivity changing material or phase change material, which contacts a first electrode and a second electrode. The cross-section of the pore defines the current through each memory cell used to reset each memory cell. The pore is formed by first using a keyhole process to define an initial opening in a dielectric material layer and then by using a spacer process to reduce the cross-section of the initial opening.

As used herein, the term “electrically coupled” is not meant to mean that the elements must be directly coupled together and intervening elements may be provided between the “electrically coupled” elements.

Write circuit 102 is electrically coupled to distribution circuit 104 though signal path 110. Distribution circuit 104 is electrically coupled to each of the memory cells 106a-106d through signal paths 112a-112d. Distribution circuit 104 is electrically coupled to memory cell 106a through signal path 112a. Distribution circuit 104 is electrically coupled to memory cell 106b through signal path 112b. Distribution circuit 104 is electrically coupled to memory cell 106c through signal path 112c. Distribution circuit 104 is electrically coupled to memory cell 106d through signal path 112d. Distribution circuit 104 is electrically coupled to sense circuit 108 through signal path 114. Sense circuit 108 is electrically coupled to controller 118 through signal path 116. Controller 118 is electrically coupled to write circuit 102 through signal path 120 and to distribution circuit 104 through signal path 122.

Each of the memory cells 106a-106d includes a phase change material that may be changed from an amorphous state to a crystalline state or from a crystalline state to an amorphous state under the influence of temperature change. The amount of crystalline phase change material coexisting with amorphous phase change material in one of the memory cells 106a-106d thereby defines two or more states for storing data within memory device 100.

In the amorphous state, a phase change material exhibits significantly higher resistivity than in the crystalline state. Therefore, the two or more states of memory cells 106a-106d differ in their electrical resistivity. In one embodiment, the two or more states include two states and a binary system is used, wherein the two states are assigned bit values of “0” and “1”. In another embodiment, the two or more states include three states and a ternary system is used, wherein the three states are assigned bit values of “0”, “1”, and “2”. In another embodiment, the two or more states include four states that are assigned multi-bit values, such as “00”, “01”, “10”, and “11”. In other embodiments, the two or more states can be any suitable number of states in the phase change material of a memory cell.

Controller 118 controls the operation of write circuit 102, sense circuit 108, and distribution circuit 104. Controller 118 includes a microprocessor, microcontroller, or other suitable logic circuitry for controlling the operation of write circuit 102, sense circuit 108, and distribution circuit 104. Controller 118 controls write circuit 102 for setting the resistance states of memory cells 106a-106d. Controller 118 controls sense circuit 108 for reading the resistance states of memory cells 106a-106d. Controller 118 controls distribution circuit 104 for selecting memory cells 106a-106d for read or write access. In one embodiment, controller 118 is embedded on the same chip as memory cells 106a-106d. In another embodiment, controller 118 is located on a separate chip from memory cells 106a-106d.

In one embodiment, write circuit 102 provides voltage pulses to distribution circuit 104 through signal path 110, and distribution circuit 104 controllably directs the voltage pulses to memory cells 106a-106d through signal paths 112a-112d. In another embodiment, write circuit 102 provides current pulses to distribution circuit 104 through signal path 110, and distribution circuit 104 controllably directs the current pulses to memory cells 106a-106d through signal paths 112a-112d. In one embodiment, distribution circuit 104 includes a plurality of transistors that controllably direct the voltage pulses or the current pulses to each of the memory cells 106a-106d.

Sense circuit 108 reads each of the two or more states of memory cells 106a-106d through signal path 114. Distribution circuit 104 controllably directs read signals between sense circuit 108 and memory cells 106a-106d through signal paths 112a-112d. In one embodiment, distribution circuit 104 includes a plurality of transistors that controllably direct read signals between sense circuit 108 and memory cells 106a-106d.

In one embodiment, to read the resistance of one of the memory cells 106a-106d, sense circuit 108 provides current that flows through one of the memory cells 106a-106d and sense circuit 108 reads the voltage across that one of the memory cells 106a-106d. In another embodiment, sense circuit 108 provides voltage across one of the memory cells 106a-106d and reads the current that flows through that one of the memory cells 106a- 106d. In another embodiment, write circuit 102 provides voltage across one of the memory cells 106a-106d and sense circuit 108 reads the current that flows through that one of the memory cells 106a-106d. In another embodiment, write circuit 102 provides current through one of the memory cells 106a-106d and sense circuit 108 reads the voltage across that one of the memory cells 106a-106d.

To program a memory cell 106a-106d within memory device 100, write circuit 102 generates a current or voltage pulse for heating the phase change material in the target memory cell. In one embodiment, write circuit 102 generates an appropriate current or voltage pulse, which is fed into distribution circuit 104 and distributed to the appropriate target memory cell 106a-106d. The amplitude and duration of the current or voltage pulse is controlled depending on whether the memory cell is being set or reset. Generally, a “set” operation of a memory cell is heating the phase change material of the target memory cell above its crystallization temperature (but usually below its melting temperature) long enough to achieve the crystalline state or a partially crystalline and partially amorphous state. Generally, a “reset” operation of a memory cell is heating the phase change material of the target memory cell above its melting temperature, and then quickly quench cooling the material, thereby achieving the amorphous state or a partially amorphous and partially crystalline state.

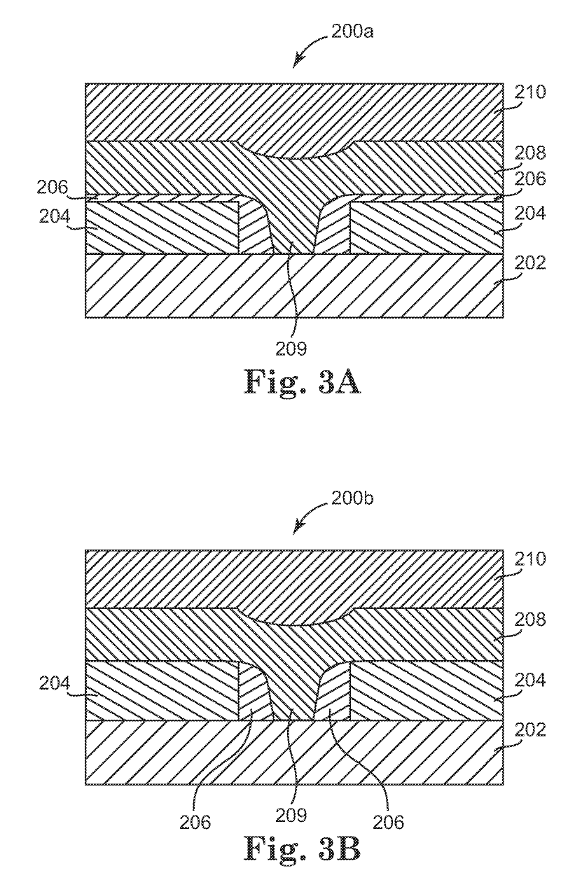

FIG. 3A illustrates a cross-sectional view of one embodiment of a phase change memory cell 200a. Phase change memory cell 200a includes a first electrode 202, a dielectric material layer 204, a spacer material layer 206, a phase change material layer 208, and a second electrode 210. First electrode 202 contacts dielectric material layer 204, spacer material layer 206, and phase change material layer 208. Phase change material layer 208 contacts spacer material layer 206 and second electrode 210. Dielectric material layer 204 and spacer material layer 206 form a pore 209 into which phase change material is deposited. In one embodiment, pore 209 has a sublithographic cross-section such that the interface between first electrode 202 and phase change material layer 208 has a sublithographic cross-section.

Read and write signals are provided to phase change material layer 208 via first electrode 202 and second electrode 210. During a write operation, the current path through phase change material 208 is from one of first electrode 202 and second electrode 210 through pore 209 to the other of first electrode 202 and second electrode 210. Phase change memory cell 200a provides a storage location in the phase change material within pore 209 for storing one or more bits of data. In one embodiment, each of the phase change memory cells 106a-106d is similar to phase change memory cell 200a.

First electrode 202 and second electrode 210 can include any suitable electrode material, such as TiN, TaN, W, Al, Ti, Ta, TiSiN, TaSiN, TiAlN, TaAlN, C, or Cu. Dielectric material layer 204 can include any suitable dielectric material, such as SiN. Spacer material layer 206 can include any suitable dielectric material, such as SiO₂ or a low-k material. Spacer material layer 206 provides a further reduction of the critical dimension (CD) of phase change memory cell 200a and improves the thermal insulation of the active region (i.e., within pore 209) of phase change material layer 208. The reduced CD and improved thermal insulation reduces the reset current used to transition memory cell 200a from a crystalline state to an amorphous state.

Phase change material 208 may be made up of a variety of materials in accordance with the present invention. Generally, chalcogenide alloys that contain one or more elements from group VI of the periodic table are useful as such materials. In one embodiment, phase change material 208 of phase change memory cell 200a is made up of a chalcogenide compound material, such as GeSbTe, SbTe, GeTe, or AgInSbTe. In another embodiment, phase change material 208 is chalcogen free, such as GeSb, GaSb, InSb, or GeGaInSb. In other embodiments, phase change material 208 is made up of any suitable material including one or more of the elements Ge, Sb, Te, Ga, As, In, Se, and S.

FIG. 3B illustrates a cross-sectional view of another embodiment of a phase change memory cell 200b. Phase change memory cell 200b is similar to phase change memory cell 200a previously described and illustrated with reference to FIG. 3A, except that in phase change memory cell 200b, spacer material layer 206 does not cover the top of dielectric material layer 204. In this embodiment, spacer material layer 204 covers the sidewalls of dielectric material layer 204. In one embodiment, each of the phase change memory cells 106a-106d is similar to phase change memory cell 200b.

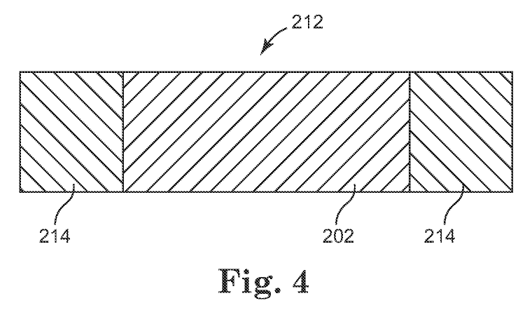

The following FIGS. 4-13 illustrate one embodiment of a process for fabricating phase change memory cells 200a and 200b previously described and illustrated with reference to FIGS. 3A and 3B.

FIG. 4 illustrates a cross-sectional view of one embodiment of a preprocessed wafer 212. Preprocessed wafer 212 includes a dielectric material 214, a first electrode 202, and lower wafer layers (not shown). Dielectric material 214 includes SiO₂, SiOₓ, SiN, fluorinated silica glass (FSG), boro-phosphorus silicate glass (BPSG), boro-silicate glass (BSG), or other suitable dielectric material. First electrode 202 includes TiN, TaN, W, Al, Ti, Ta, TiSiN, TaSiN, TiAlN, TaAlN, C, Cu, or other suitable electrode material. Dielectric material 214 laterally surrounds first electrode 202 and isolates first electrode 202 from adjacent device features.

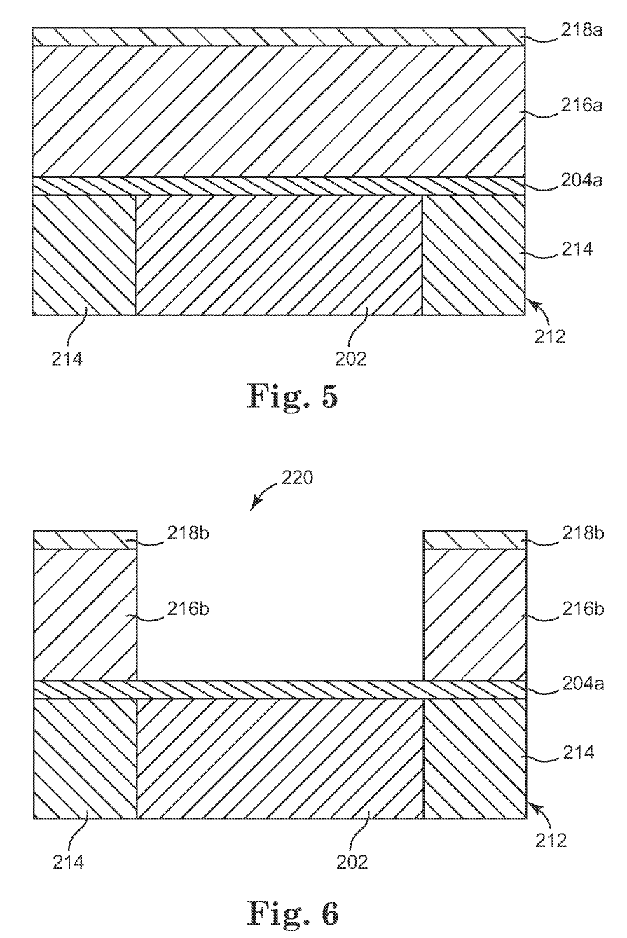

FIG. 5 illustrates a cross-sectional view of one embodiment of preprocessed wafer 212, a first dielectric material layer 204a, a second dielectric material layer 216a, and a third dielectric material layer 218a. A dielectric material, such as SiN or other suitable dielectric material is deposited over preprocessed wafer 212 to provide first dielectric material layer 204a. First dielectric material layer 204a is deposited using chemical vapor deposition (CVD), atomic layer deposition (ALD), metal organic chemical vapor deposition (MOCVD), plasma vapor deposition (PVD), jet vapor deposition (JVD), or other suitable deposition technique.

A second dielectric material different than the dielectric material of first dielectric material layer 204a, such as SiO₂ or other suitable material is deposited over first dielectric material layer 204a to provide second dielectric material layer 216a. Second dielectric material layer 216a is thicker than first dielectric material layer 204a. In one embodiment, second dielectric material layer 216a is at least four times thicker than first dielectric material layer 204a. Dielectric material layer 216a is deposited using CVD, ALD, MOCVD, PVD, JVD, or other suitable deposition technique.

A third dielectric material similar to the dielectric material of dielectric material layer 204a, such as SiN or other suitable material is deposited over second dielectric material layer 216a to provide third dielectric material layer 218a. Third dielectric material layer 218a is thinner than second dielectric material layer 216a. In one embodiment, third dielectric material layer 218a has substantially the same thickness as first dielectric material layer 204a. Third dielectric material layer 218a is deposited using CVD, ALD, MOCVD, PVD, JVD, or other suitable deposition technique.

FIG. 6 illustrates a cross-sectional view of one embodiment of preprocessed wafer 212, first dielectric material layer 204a, second dielectric material layer 216b, and third dielectric material layer 218b after etching third dielectric material layer 218a and second dielectric material layer 216a. Third dielectric material layer 218a and second dielectric material layer 216a are etched to provide opening 220 exposing first dielectric material layer 204a and to provide second dielectric material layer 216b and third dielectric material layer 218b. In one embodiment, opening 220 is substantially centered over first electrode 202.

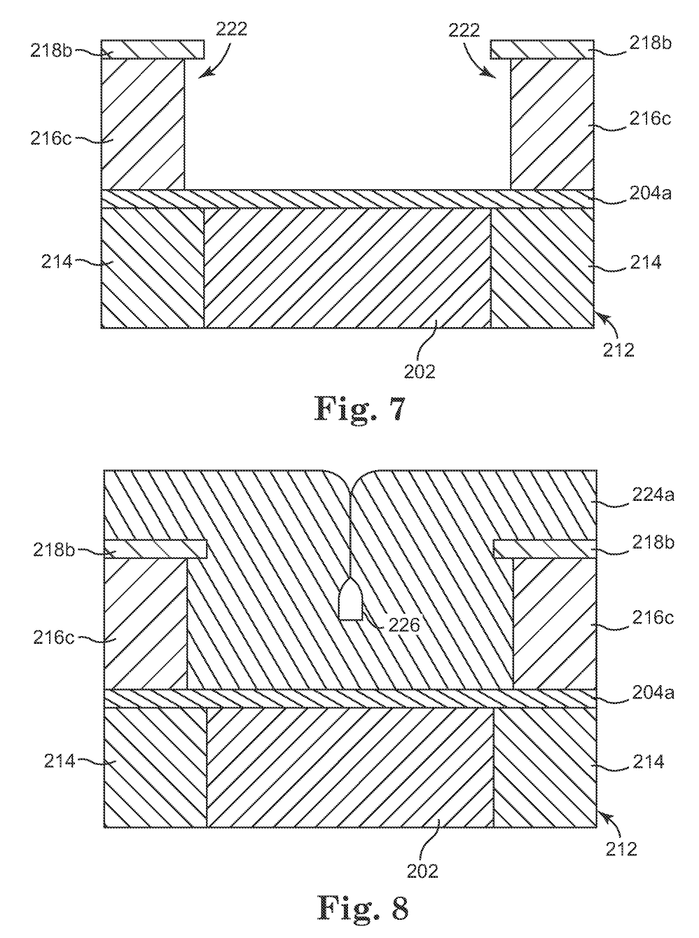

FIG. 7 illustrates a cross-sectional view of one embodiment of preprocessed wafer 212, first dielectric material layer 204a, second dielectric material layer 216c, and third dielectric material layer 218b after etching second dielectric material layer 216b. Second dielectric material layer 216b is selectively recess etched using a selective wet etch or other suitable etch to create overhang of third dielectric material layer 218b as indicated at 222.

FIG. 8 illustrates a cross-sectional view of one embodiment of preprocessed wafer 212, first dielectric material layer 204a, second dielectric material layer 216c, third dielectric material layer 218b, and a keyhole 226 formed in a poly-Si layer 224a. Poly-Si or other suitable material is conformally deposited over exposed portions of third dielectric material layer 218b, second dielectric material layer 216c, and first dielectric material layer 204a. Due to overhang 222, the conformal deposition of poly-Si pinches itself off forming a void or keyhole 226. Keyhole 226 is substantially centered over first electrode 202. Poly-Si layer 224a is deposited using CVD, ALD, MOCVD, PVD, JVD, or other suitable deposition technique.

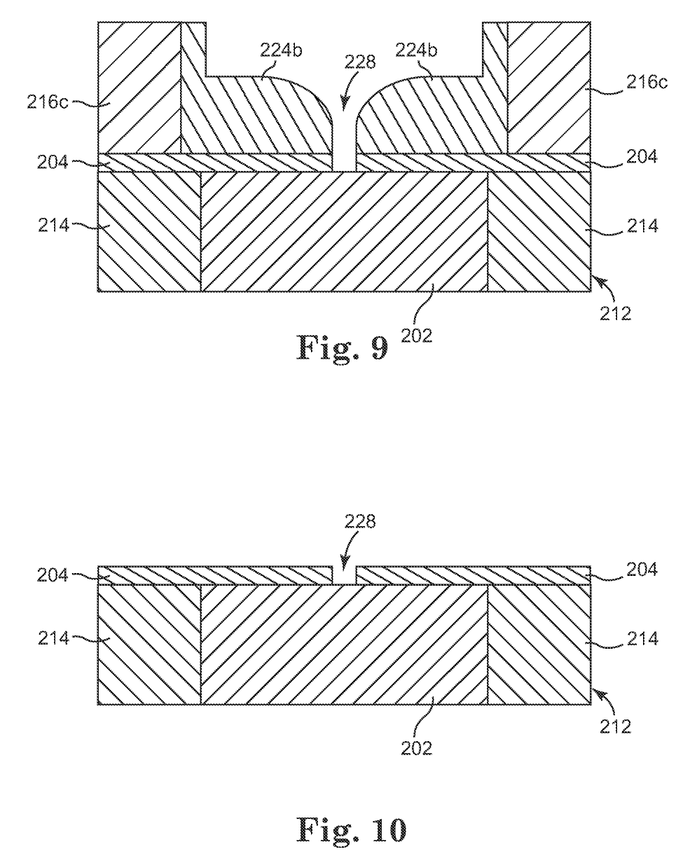

FIG. 9 illustrates a cross-sectional view of one embodiment of preprocessed wafer 212, first dielectric material layer 204, second dielectric material layer 216c, and poly-Si layer 224b after etching poly-Si layer 224a and first dielectric material layer 204a. Third dielectric material layer 218b is removed. Poly-Si layer 224a is etched to expose keyhole 226. Keyhole 226 is then transferred into first dielectric material layer 204a as indicated by opening 228 to provide poly-Si layer 224b and first dielectric material layer 204. In one embodiment, opening or pore 228 has a sublithographic cross-section such that the exposed portion of first electrode 202 has a sublithographic cross-section.

FIG. 10 illustrates a cross-sectional view of one embodiment of preprocessed wafer 212 and first dielectric material layer 204 after removing poly-Si layer 224b and second dielectric material layer 216c. Second dielectric material layer 216c and poly-Si layer 224b are etched to expose first dielectric material layer 204.

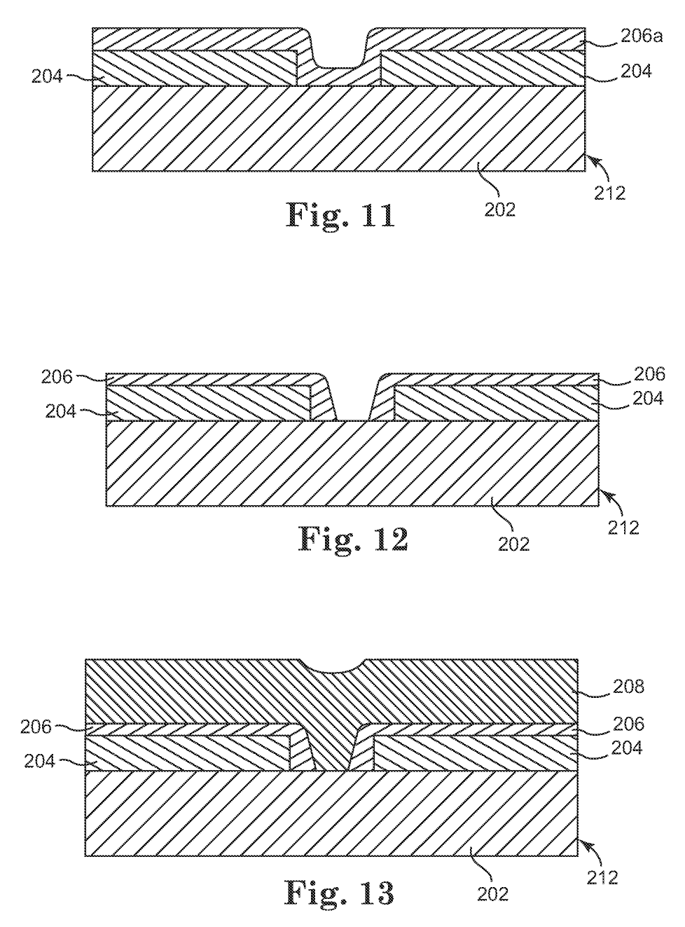

FIG. 11 illustrates a cross-sectional view of one embodiment of preprocessed wafer 212, first dielectric material layer 204, and a spacer material layer 206a. A spacer material, such as SiO₂, low-k material or other suitable spacer material is conformally deposited over exposed portions of dielectric material layer 204 and first electrode 202 to provide spacer material layer 206a. Spacer material layer 206a is deposited using CVD, ALD, MOCVD, PVD, JVD, or other suitable deposition technique.

FIG. 12 illustrates a cross-sectional view of one embodiment of preprocessed wafer 212, first dielectric material layer 204, and spacer material layer 206 after etching spacer material layer 206a. Spacer material layer 206a is spacer etched to expose a portion of first electrode 202 and provide spacer material layer 206. In one embodiment, after etching, spacer material remains on both the top and sidewalls of first dielectric material layer 204. In another embodiment, after etching, spacer material remains on the sidewalls of first dielectric material layer 204 but not on the top of dielectric material layer 204 as previously described and illustrated with reference to FIG. 3B.

FIG. 13 illustrates a cross-sectional view of one embodiment of preprocessed wafer 212, first dielectric material layer 204, spacer material layer 206, and a phase change material layer 208. A phase change material, such as a calcogenide compound material or other suitable phase change material is deposited over exposed portions of spacer material layer 206 and first electrode 202 to provide phase change material layer 208. Phase change material layer 208 is deposited using CVD, ALD, MOCVD, PVD, JVD, or other suitable deposition technique.

An electrode material, such as TiN, TaN, W, Al, Ti, Ta, TiSiN, TaSiN, TiAlN, TaAlN, C, Cu, or other suitable electrode material is deposited over phase change material layer 208 to provide second electrode 210 and phase change memory cell 200a as previously described and illustrated with reference to FIG. 3A. The electrode material is deposited using CVD, ALD, MOCVD, PVD, JVD, or other suitable deposition technique. In another embodiment, where spacer material layer 206 remains on the sidewalls of first dielectric material layer 204 but not on the top of dielectric material layer 204, phase change memory cell 200b as previously described and illustrated with reference to FIG. 3B is fabricated.

Embodiments of the present invention provide a phase change memory cell having a pore into which phase change material is deposited. The pore is defined using a keyhole process and then further reduced by a spacer process. The spacer material further reduces the critical dimension of the memory cell and improves the thermal insulation of the active region of the memory cell. The reduced critical dimension and improved thermal insulation reduce the reset current used to transition the phase change material from a crystalline state to an amorphous state.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a first electrode;
a dielectric material layer contacting a first portion of the first electrode;
a spacer material layer contacting a top portion and a sidewall portion of the dielectric material layer and a second portion of the first electrode, the second portion within the first portion;
resistivity changing material contacting the spacer material layer and a third portion of the first electrode, the third portion within the second portion; and
a second electrode contacting the resistivity changing material.

2. The integrated circuit of claim 1, wherein the third portion of the first electrode has a sublithographic cross-section.

3. The integrated circuit of claim 1, wherein the dielectric material layer comprises SiN.

4. The integrated circuit of claim 1, wherein the spacer material layer comprises one of SiO₂ and a low-k material.

5. The integrated circuit of claim 1, wherein the resistivity changing material comprises at least one of Ge, Sb, Te, Ga, As, In, Se, and S.

6. A system comprising:
a host; and
a memory device communicatively coupled to the host, the memory device comprising:
a phase change memory cell including a phase change material deposited into a pore, the phase change material contacting a first electrode and a second electrode, the pore defined by an opening in a dielectric material layer and a spacer material layer that reduces a cross-section of the opening, the spacer material layer contacting top and sidewall portions of the dielectric material layer.

7. The system of claim 6, wherein the memory device further comprises:
a write circuit for writing data to the memory cell; and
a sense circuit for reading data from the memory cell.

8. The system of claim 7, wherein the memory device further comprises:
a controller configured to control the write circuit and the sense circuit.

9. The system of claim 6, wherein the memory device further comprises:
a distribution circuit configured to access the phase change memory cell.

10. A memory cell comprising:
a first electrode;
a second electrode;
phase change material between the first electrode and the second electrode;
means for forming an active area of the phase change material; and
means for reducing a cross-section of the active area.

11. The memory cell of claim 10, wherein the phase change material comprises at least one of Ge, Sb, Te, Ga, As, In, Se, and S.

12. The memory cell of claim 10, wherein the first electrode comprises one of TiN, TaN, W, Al, Ti, Ta, TiSiN, TaSiN, TiAlN, TaAlN, C, and Cu.

13. A method for fabricating an integrated circuit, the method comprising:
providing a preprocessed wafer including a first electrode;
depositing a dielectric material layer over the preprocessed wafer;
etching an opening in the dielectric material layer to expose a first portion of the first electrode;
conformally depositing a spacer material layer over exposed portions of the dielectric material layer and the first electrode;
spacer etching the spacer material layer to expose a second portion of the first electrode while maintaining spacer material over the dielectric material layer;
depositing a phase change material layer over the spacer material layer and the second portion of the first electrode; and
fabricating a second electrode contacting the phase change material layer.

14. The method of claim 13, wherein etching the opening in the dielectric material layer comprises etching the opening in the dielectric material layer by using a keyhole process to form a mask for etching the opening.

15. The method of claim 13, wherein spacer etching the spacer material layer comprises spacer etching the spacer material layer to expose a second portion of the first electrode having a sublithographic cross-section.

16. The method of claim 13, wherein depositing the dielectric material layer comprises depositing SiN.

17. The method of claim 13, wherein depositing the spacer material layer comprises depositing one of SiO₂ and a low-k material.

18. The method of claim 13, wherein depositing the phase change material layer comprises depositing at least one of Ge, Sb, Te, Ga, As, In, Se, and S.

19. A method for fabricating a memory cell, the method comprising:
providing a preprocessed wafer including a first electrode;
depositing a first dielectric material layer over the preprocessed wafer;
depositing a second dielectric material layer over the first dielectric material layer;
depositing a third dielectric material layer over the second dielectric material layer;
etching the second and third dielectric material layers to provide an opening and to expose a portion of the first dielectric material layer;
recess etching the etched second dielectric material layer to provide an overhang of the etched third dielectric material layer;
conformally depositing a poly-Si layer over exposed portions of the first dielectric material layer, the recess etched second dielectric material layer, and the etched third dielectric material layer to form a keyhole;
transferring the keyhole to the first dielectric material layer by etching the first dielectric material layer to expose a portion of the first electrode;
removing the second dielectric material layer, the third dielectric material layer, and the poly-Si layer;
conformally depositing a spacer material layer over exposed portions of the dielectric material layer and the first electrode;
spacer etching the spacer material layer to expose a second portion of the first electrode;
depositing a phase change material layer over the spacer material layer and the second portion of the first electrode; and
fabricating a second electrode contacting the phase change material layer.

20. The method of claim 19, wherein spacer etching the spacer material layer comprises spacer etching the spacer material layer to expose the second portion of the first electrode while maintaining spacer material over the dielectric material layer.

21. The method of claim 19, wherein spacer etching the spacer material layer comprises spacer etching the spacer material layer to expose a second portion of the first electrode having a sublithographic cross-section.

22. The method of claim 19, wherein depositing the dielectric material layer comprises depositing SiN.

23. The method of claim 19, wherein depositing the spacer material layer comprises depositing one of SiO₂ and a low-k material.

24. The method of claim 19, wherein depositing the phase change material layer comprises depositing at least one of Ge, Sb, Te, Ga, As, In, Se, and S.
